(19) United States
(12) Patent Application Publication
(10) Pub. No.: US 2009/0008131 A1
(43) Pub. Date: Jan. 8, 2009

(54) Flexible printed-circuit board

(76) Inventors: Osamu Shibata, Hyogo (JP); Takeshi Nakayama, Hyogo (JP); Yoshiyuki Saito, Osaka (JP)

Correspondence Address: WENDEROTH, LIND & PONACK L.L.P., 2033 K. STREET, NW, SUITE 800, WASHINGTON, DC, 20006, US

(21) Appl. No.: 11/659,131

(22) PCT Filed: Jul. 28, 2005
(86) PCT No.: PCT/JP2005/013824

§ 371 Date: Feb. 1, 2007

(30) Foreign Application Priority Data
Aug. 2, 2004 (JP) 2004-225067

(51) Int. Cl. H05K 1/02

(52) U.S. Cl. 174/254

(57) ABSTRACT

A flexible printed board that is adapted to high-speed transmission and can mount a plurality of connectors at low cost is provided. The board comprises a flexible printed board body 100 that has a first side 100a and a second side 100b opposed to each other, and an overlap portion 105 formed by bending its one end; a plurality of wiring lines 101 that are arranged on the first side 100a of the body substantially in parallel to each other; first pads 103 that are connected to respective ends of wiring lines, wider than the wiring lines and formed on the first-side surface 105a of the overlap potion; and second pads 104 that are located at respective ends of wiring lines, wider than the wiring lines and formed on the second-side surface 105b of the overlap potion. The wiring lines 101a with the first pads connected thereto and the wiring lines 101b with the second pads 104 connected thereto are alternatively arranged on the first side.

### TECHNICAL FIELD

The present invention relates to a flexible printed board that is used, in computer terminals or electric devices such as AV equipment, for signal transmission.

### BACKGROUND ART

Recently, a serial interface such as USB (Universal Serial Bus), IEEE (Institute of Electrical and Electric Engineers) 1394 is popular in computer terminals such as PC (personal computer), and electric devices such as AV equipment, and models adapted thereto has increased. Accordingly, the number of interface ports included in one electric device has increased. In addition, in an electric device, a flexible printed board that is easily routed is generally used as a transmission media for relaying signals. In terms of such a background, a flexible printed board that can transmit signals at high speed and has a plurality of connector ports is required.

In order that a flexible board may transmit signals at high speed, a board with wiring provided on its both sides (double-sided board) is generally used. In a double-sided board, a signal wiring pattern is formed on the front side, while a ground wiring pattern is formed on the back side. Transmission lines including signal wiring and ground wiring are designed in consideration of signal reflection and cross talk noise. As compared with a single-sided board with transmission lines provided only on its one side, a double-sided board has advantages that easily achieves low impedance and has excellent high frequency characteristics. On the other hand, there is a problem that the cost of a double-sided board is high. To solve this problem, Patent Document 1 has proposed technique that employs inexpensive single-sided board and adjusts transmission line characteristic impedance.

However, a flexible board that can mount a plurality of connectors and prevents signal reflection and cross talk at low cost has not been proposed yet. The aforementioned Patent Document 1 dose not propose technique that suppresses signal reflection and cross talk noise produced in the case where a plurality of connectors are mounted to a flexible board. If a plurality of connectors are mounted on one side in a simple manner, as shown in FIG. 8, a mount area increases in response to the number of the connectors, thus, its cost increases. Furthermore, as shown in FIG. 9, if a plurality of connectors are mounted to a double-sided board with a mount area reduced in a simple manner without consideration of terminal arrangement, problems such as signal reflection and cross talk arise, thus, it is difficult to transmit signals at high speed.

The present invention is aimed at solving the above conventional problems, and providing a flexible printed board with features that can mount a plurality of connectors with an inexpensive single-sided board, and suppresses signal reflection and cross talk. Patent Document 1: Japanese unexamined patent application 2000-357846.

### DISCLOSURE OF INVENTION

To solve the above problems, a first aspect of the present invention provides a flexible printed board having the following features.

A flexible printed board body that has mutually opposing first and second sides, and an overlap portion that overlaps the second side such that the first side becomes the outer surface thereof by bending at least a part of said first side.

A plurality of wiring lines that are arranged on the first side of said body substantially in parallel to each other.

First pads that are connected to ends and/or midway points of a portion of the wiring lines, the first pads wider than the wiring lines connected thereto, and formed on one side of said overlap portion.

Second pads that are connected to ends and/or midway points of a portion of the wiring lines, the second pads wider than the wiring lines connected thereto, and formed on the other side of said overlap portion.

The wiring lines with said first pads connected thereto and the wiring lines with said second pads connected thereto are alternately arranged on said first side.

Since the wiring lines are formed only on the first side, the board area can be small, thus, it is possible to suppress the cost of the board. On the other hand, since the pads that connect connectors are formed on the front and back sides of the overlap portion, in other words, they are formed on the both sides, a plurality of connectors can be connected. That is, it is possible to achieve a flexible printed board that is adapted to a plurality of connectors, and easily controls impedance at low cost. In addition, the overlap portion where the pads can be formed not only on an end of flexible printed board but also in a midway point, and additionally may be formed at a plurality points.

A second aspect of the present invention according to the first aspect provides a flexible printed board, wherein said wiring lines includes signal wiring lines and ground wiring lines, and said signal wiring lines and said ground wiring lines are arranged so as to alternate every two lines.

Since a first pad arrangement and a second pad arrangement alternatively arrange signal pads and ground pads, it is possible to relieve cross talk effect between the signal pads.

A third aspect of the present invention according to the second aspect provides a flexible printed board, wherein the distance between the signal wiring lines adjacent to each other is longer than the distance between the ground wiring lines adjacent to each other.

Since the distance between the signal wiring lines is large, it is possible to prevent cross talk between the signal wiring lines.

A fourth aspect of the present invention according to the first aspect provides a flexible printed board, wherein a wiring pattern composed of repeating wiring pattern units each composed of three wiring lines is formed on said first side. In this case, each of the wiring pattern units is formed of a ground wiring line and two signal wiring lines that are arranged so as to interpose the ground line therebetween.

Since, in the overlap portion of the board body, a ground terminal on other side is located between a signal terminal and a signal terminal, it is possible to relieve cross talk of the signal terminals.

A fifth aspect of the present invention according to the fourth aspect provides a flexible printed board, wherein the two signal wiring lines included in said wiring pattern unit are a first signal wiring line and a second signal wiring line that have signal phases inverted from each other. In this case, in each of said wiring pattern units, said first signal wiring line and said second signal wiring line are arranged symmetrically with respect to said ground wiring line.

Since the ground wiring line is located between differential wiring lines of positive phase and inverted phase, it is possible to relieve cross talk of the positive-phase and inverted-phase signals of the differential signals.

A sixth aspect of the present invention according to the fourth aspect provides a flexible printed board, wherein the distance between said wiring pattern units that compose said wiring pattern is longer than the distance between the signal wiring line and the ground wiring line in each of said wiring pattern units.

Since, in the wiring pattern units adjacent to each other, positive-phase and inverted-phase wiring lines of the differential signals are located adjacent to each other, increase of distance of wiring pattern unit can suppress effect of cross talk between signal wiring lines.

When the present invention is used, it is possible to provide a flexible printed board that can mount a plurality of connectors at low cost.

### BRIEF DESCRIPTION OF DRAWINGS

FIG. 1

Construction views of a flexible printed board according to a first embodiment of the present invention

(a) Plan view
(b) Developed plan view
(c) Side view when viewed from a direction A in Fig. (a)
(d) Side view when viewed from a direction B in Fig. (a)
(e) Cross-sectional view of an overlap portion of Fig. (a)

FIG. 2

Construction views of a flexible printed board according to a second embodiment of the present invention

(a) Plan view
(b) Developed plan view
(c) Cross-sectional view of an overlap portion of Fig. (a)

FIG. 3

Construction views of a flexible printed board according to a third embodiment of the present invention

(a) Plan view
(b) Developed plan view
(c) Cross-sectional view of an overlap portion of Fig. (a)

FIG. 4

Construction views of a flexible printed board according to alternate embodiment

(a) Plan view
(b) Developed plan view
(c) Cross-sectional view of an overlap portion of Fig. (a)

FIG. 5

Construction views of a flexible printed board according to alternate embodiment

(a) Plan view
(b) Developed plan view
(c) Cross-sectional view of an overlap portion of Fig. (a)

FIG. 6

Construction views of a flexible printed board according to alternate embodiment

(a) Plan view of a developed flexible printed board according to this embodiment
(b) Side view of the flexible printed board when viewed from a side A in the same Fig. (a)
(c) Side view of the flexible printed board when viewed from a side B in the same Fig. (a)
(d) Perspective view of the flexible printed board when viewed from one direction
(e) Perspective view of the flexible printed board when viewed from another direction

FIG. 7

Explanation view showing an application example of construction shown in FIG. 6

FIG. 8

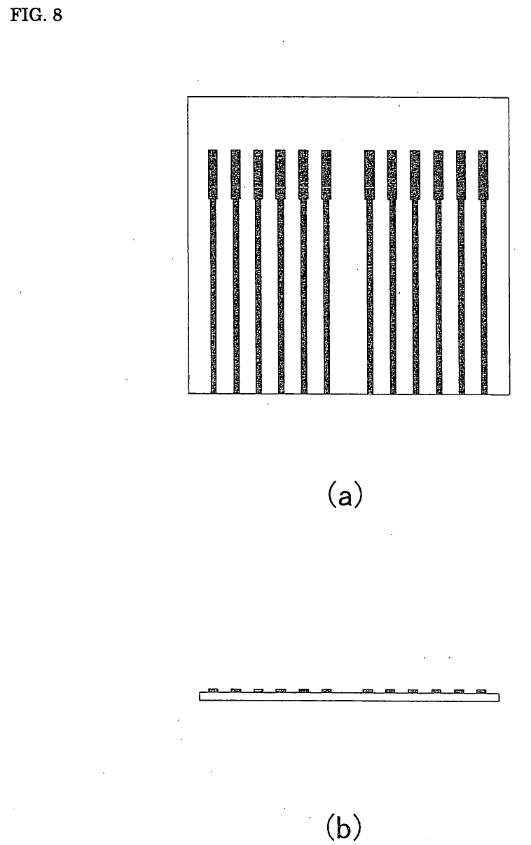

Conventional construction view (in the case of single-sided board)

FIG. 9

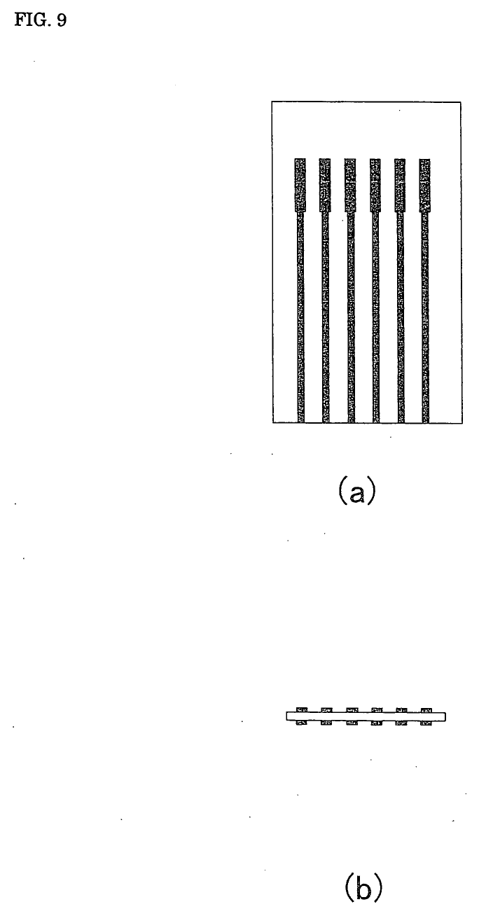

Conventional construction view (in the case of double-sided board)

### BEST MODE FOR CARRYING OUT THE INVENTION

Hereafter, the present invention will be specifically described with reference to the drawings.

### First Embodiment

### [Construction]

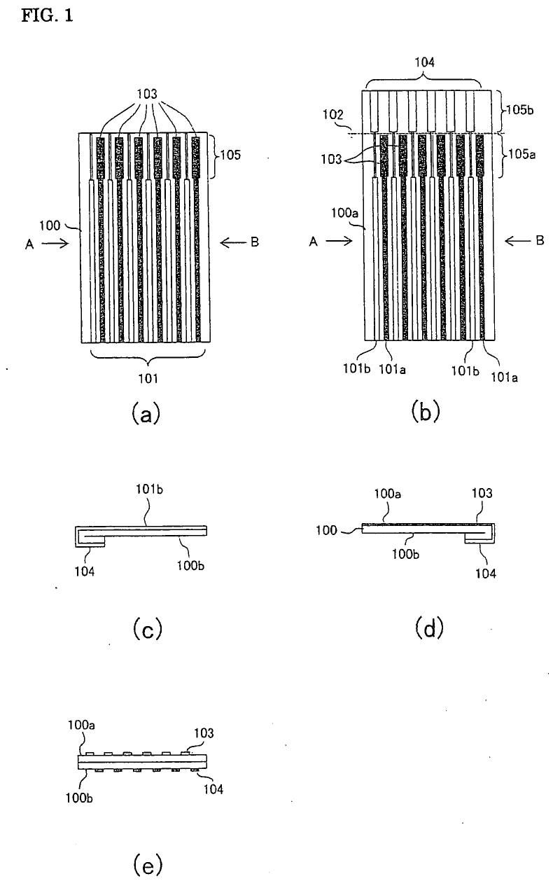

FIG. 1 shows a construction view of a flexible printed board according to a first embodiment example of the present invention. FIG. 1(a) is a plan view of the flexible printed circuit board according to this embodiment. The flexible printed board includes a body 100, wiring lines 101, and front-side pads 103. This flexible board is doubled in an overlap portion 105. The board includes back-side pads 104 (see FIGS. 1(c) and (d)) on the side of the overlap portion 105 opposite to the paper plane in the figure.

FIG. 1(b) is a plan view of the flexible printed circuit board with the overlap portion 105 being developed. The overlap portion 105 is developed to a front side 105a and a back side 105b. As discussed above, the back-side pads 104 are formed on the back side of the overlap portion 105. FIG. 1(c) is a side view of the flexible printed board when viewed from a direction A in the same Fig. (a). FIG. 1(d) is a side view of the flexible printed board when viewed from a direction B in the same Fig. (a). FIG. 1(e) is a cross-sectional view of the overlap portion 105 in the same Fig. (a).

Each component is now described in detail.

### (1) Body

The sheet-shaped body 100 has a front side 100a and a back side 100b opposed to each other, and is bendable. One end of the body 100 is bent at a bending line 102 in FIG. 1(b) such that the front side 100a becomes outside. Parts of the back side 100b of the bent body 100 are joined to each other with a heat-resistant adhesive agent or the like. The bent part defines the overlap portion 105 where the body 100 is doubled.

### (2) A Plurality of Wiring Lines

A plurality of wiring lines 101 are arranged substantially in parallel to each other on the surface of the body 100. The wiring lines 101 are conductive wiring lines that transmit signals. The number of wiring lines 101 is not limited to twelve lines in the illustration. The wiring lines 101 are broadly classified into wiring lines 101a connected to the front-side pads 103, and wiring line 101b connected to back-side pads 104. The wiring lines 101a and the wiring lines 101b are alternately arranged on the front side 100a of the body 100. The reason is that, on the back between the pads on one side of the overlap portion 105, the pads on the other side are arranged.

In the overlap portion 105, the width of wiring line 101b is formed so as to be narrower than other part. The reason is to provide a sufficient distance between the wiring line 101b and the front-side pad 103 in the overlap portion 105 and thus to relieve cross talk. Preferably, in the case where the distance between the wiring line 101b and the front-side pad 103 in the overlap portion 105 is provided as the same as the distance between the wiring lines 101a and 101b in other part, the impedance of each wiring line can be stable.

### (3) Front-Side Pads and Back-Side Pads

The front-side pads 103 and the back-side pads 104 for connector connection are formed in the body 100. The front-side pads 103 and the back-side pads 104 are connected to respective ends of wiring lines 101, and are formed so as to be wider than the wiring lines 101. In addition, the front-side pads 103 are formed on the overlap portion front side 105a. The front-side pads 103 are connected to the wiring lines 101a on the front side 100a of the body 100. On the other hand, the back-side pads 104 are formed on the overlap portion back side 105b. The back-side pads 104 are connected to the wiring lines 101b that turn from the front side to the back side of the overlap portion 105 on the overlap portion back surface side 105b.

As shown in FIG. 1(e), on the back between the pads on one side of the overlap portion 105, the pads on the other side are arranged. Accordingly, in each of the front side 105a and the back surface side 105b of the overlap portion, it is possible to provide a sufficient distance between the pads. In addition, it is possible to provide a sufficient distance between the pad on the front side 105a and the pad on the back surface side 105b of the overlap portion. Therefore, cross talk between the pads is easily relieved. Additionally, the interval between the pads on the both front and back sides is easily set, thus, it is suitable to mount a connector.

It should be appreciated that, although the overlap portion 105 is formed at one location to mount two connectors on its both sides in this embodiment, overlap portions 105 may be formed at a plurality of locations. Three or more connectors can be mounted. Furthermore, the connectors to be mounted to this flexible printed board can be separate connectors on the front and back sides, or can be a connector that is integrated so as to be used for the front and back sides.

It should be appreciated that all the wiring lines necessarily have the aforementioned construction, but some lines of the wiring lines may have it.

### [Effect]

According to the flexible printed board of the aforementioned construction, since the wiring lines 101 are formed only on one side, the area of the flexible printed board can be small, thus, it is possible to suppress its cost. On the other hand, since the pads 103 and 104 that connect connectors are formed on the front and back sides of the overlap portion 105, in other words, they are formed on the both sides of the board, a plurality of connectors can be connected to the board. That is, it is possible to achieve a flexible printed board that is adapted to a plurality of connectors, and easily controls impedance at low cost.

### Second Embodiment

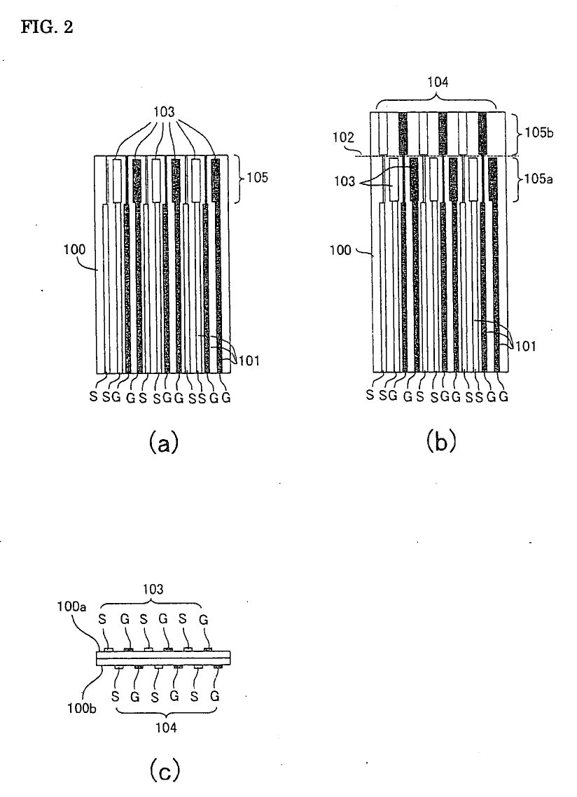

FIG. 2 shows a construction view of a flexible printed board according to a second embodiment example of the present invention. FIG. 2(a) is a plan view of the flexible printed circuit board according to this embodiment. The flexible printed board includes a body 100, wiring lines 101, and front-side pads 103. This flexible board is doubled in an overlap portion 105. The board includes back-side pads 104 (see FIGS. 2(b) and (c)) on the side of the overlap portion 105 opposite to the paper plane in the figure. FIG. 2(b) is a plan view of the flexible printed circuit board with the overlap portion 105 being developed. The overlap portion 105 is developed to a front side 105a and a back side 105b. The same Fig. (c) is a cross-sectional view of the overlap portion 105 in the same Fig. (a).

Each component is now described in detail. In the drawings, the components that is attached with the same reference numerals have construction and action similar to the foregoing first embodiment.

### (1) Body

The sheet-shaped body 100 has a front side 100a and a back side 100b opposed to each other, and is bendable. One end of the body 100 is bent at a bending line 102 in FIG. 2(b) such that the front side 100a becomes outside. Parts of the back side 100b of the bent body 100 are joined to each other with a heat-resistant adhesive agent or the like. The bent part defines the overlap portion 105 where the body 100 is doubled.

### (2) A Plurality of Wiring Lines

A plurality of wiring lines 101 are arranged substantially in parallel to each other on the surface of the body 100. The wiring lines 101 are conductive wiring lines that transmit signals. The number of wiring lines 101 is not limited to twelve lines in the illustration. The wiring lines 101 are broadly classified into wiring lines 101a connected to the front-side pads 103, and wiring line 101b connected to back-side pads 104. The wiring lines 101a and the wiring lines 101b are alternately arranged on the front side 100a of the body 100. The reason is that, on the back between the pads on one side of the overlap portion 105, the pads on the other side are arranged.

In the overlap portion 105, the width of wiring line 101b is formed so as to be narrower than other part. The reason is to provide a distance as large as possible between the wiring line 101b and the front-side pad 103 in the overlap portion 105 and thus to relieve signal reflection and cross talk.

The wiring lines 101 can be classified into signal wiring lines S and ground wiring lines G. The signal wiring lines S and the ground wiring lines G are alternatively arranged every two lines. In this case, since, in each of the front side 105a and the back side 105b of the overlap portion, signal pads and ground pads are alternatively arranged, it is possible to relieve cross talk effect between the signal pads. In addition, since the impedance of the line and the pad is ensured, desired impedance can be designed based on adjustment of material, line width, and line thickness. Note that a pad that is connected to the signal wiring line S, and a pad that is connected to the ground wiring line G are referred to as the signal pad, and the ground pad.

The distance between the signal wiring lines S adjacent to each other is preferably provided so as to be as large as possible. The reason is to prevent cross talk and signal reflection between the signal wiring lines. Since the area of the body 100 is limited, actually, the distance between the signal wiring lines S adjacent to each other is preferably set so as to be larger than the distance between the signal wiring line S and the ground wiring line G adjacent to each other.

### (3) Front-Side Pad and Back-Side Pad

The front-side pads 103 and back-side pads 104 for connector connection are formed in the body 100. The front-side pads 103 and the back-side pads 104 are connected to respective ends of wiring lines 101, and are formed so as to be wider than the wiring lines 101. In addition, the front-side pads 103 are formed on the overlap portion front side 105a. The front-side pads 103 are connected to the wiring lines 101a on the front side 100a of the body 100. On the other hand, the back-side pads 104 are formed on the overlap portion back side 105b. The back-side pads 104 are connected to the wiring lines 101b that turn from the front side to the back side of the overlap portion 105 on the overlap portion back surface side 105b.

As shown in FIG. 1(e), on the back between the pads on one side of the overlap portion 105, the pads on the other side are arranged. Accordingly, in each of the front side 105a and the back surface side 105b of the overlap portion, a sufficient distance between the pads is easily provided. In addition, a sufficient distance between the pad on the front side 105a and the pad on the back surface side 105b is easily provided. Therefore, cross talk between the pads is easily relieved. Additionally, in the case where the intervals between the pads on the both front and back sides are set as the same as each other, it is suitable to mount a connector.

In addition, the front-side pads 103 and the back-side pads 104 can be classified into the signal pad and the ground pad. As shown in FIG. 2(c), in each of the front side 105a and the back surface side 105b of overlap portion, the signal pad and the ground pad are alternately arranged. Accordingly, it is possible to relieve reflection and cross talk between the signal pads. In addition, since the impedance of the line and the pad is ensured, desired impedance can be designed based on adjustment of material, line width, and line thickness.

Additionally, a plurality of overlap portions can be formed to mount three or more connectors similarly to the first embodiment. Furthermore, the connectors to be mounted to this flexible printed board can be separate connectors on the front and back sides, or can be a connector that is partially integrated or is integrated so as to be used for the front and back sides similarly to the first embodiment.

### [Effect]

According to the flexible printed board of the aforementioned construction, since the wiring lines 101 are formed only on one side, the area of the flexible printed board can be small, thus, it is possible to suppress its cost. On the other hand, since the pads 103 and 104 that connect connectors are formed on the front and back sides of the overlap portion 105, in other words, they are formed on the both sides of the board, a plurality of connectors can be connected to the board. In addition, the signal wiring lines S and the ground wiring lines G are alternatively arranged every two lines, thus, in each of the front side 105a and the back side 105b of the overlap portion, signal pads and ground pads can be alternatively arranged, as a result, it is possible to relieve reflection and cross talk between the signal pads. Additionally, since the impedance of the line and the pad is ensured, desired impedance can be designed based on adjustment of material, line width, and line thickness. Furthermore, since the distance between the signal wiring lines S is provided so as to be larger than the distance between the signal wiring line S and the ground wiring line G, it is possible to relieve reflection and cross talk between the signal wiring lines S. That is, it is possible to achieve a flexible printed board that is adapted to a plurality of connectors, and is suitable for high-speed transmission at low cost.

### Third Embodiment

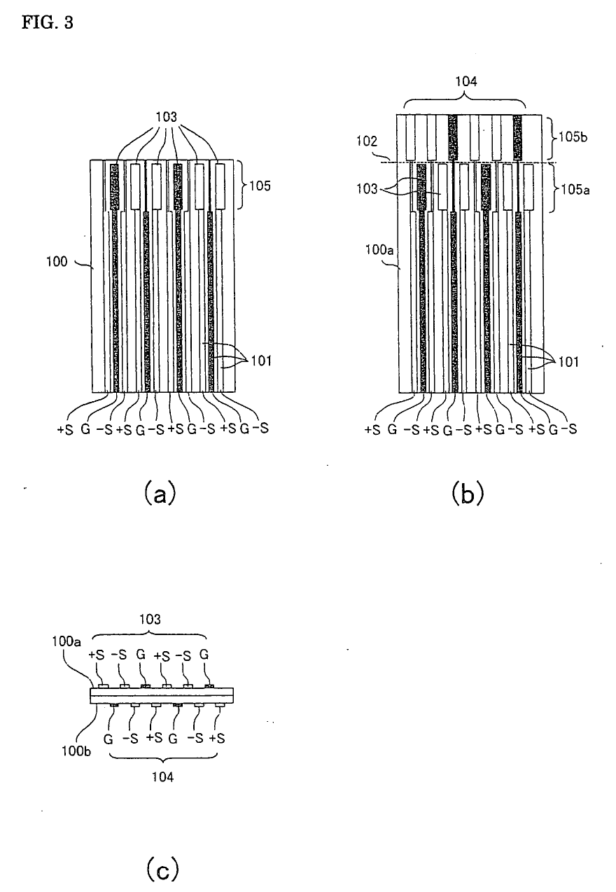

FIG. 3 shows a construction view of a flexible printed board according to a third embodiment of the present invention. FIG. 3(a) is a plan view of the flexible printed circuit board according to this embodiment. The flexible printed board includes a body 100, wiring lines 101, and front-side pads 103. This flexible board is doubled in an overlap portion 105. The board includes back-side pads 104 (see FIGS. 3(b) and (c)) on the side of the overlap portion 105 opposite to the paper plane in the figure. FIG. 3(b) is a plan view of the flexible printed circuit board with the overlap portion 105 being developed. The overlap portion 105 is developed to a front side 105a and a back side 105b. FIG. 3(c) is a cross-sectional view of the overlap portion 105 in the same Fig. (a).

Each component is now described in detail. In the drawings, the components that is attached with the same reference numerals have construction and action similar to the foregoing first embodiment.

### (1) Body

The sheet-shaped body 100 has a front side 100a and a back side 100b opposed to each other, and is bendable. One end of the body 100 is bent at a bending line 102 in FIG. 3(b) such that the front side 100a becomes outside. Parts of the back side 100b of the bent body 100 are joined to each other with a heat-resistant adhesive agent or the like. The bent part defines the overlap portion 105 where the body 100 is doubled.

### (2) A Plurality of Wiring Lines

A plurality of wiring lines 101 are arranged substantially in parallel to each other on the surface of the body 100. The wiring lines 101 are conductive wiring lines that transmit signals. The number of wiring lines 101 is not limited to twelve lines in the illustration. The wiring lines 101 are broadly classified into wiring lines 101a connected to the front-side pads 103, and wiring line 101b connected to back-side pads 104. The wiring lines 101a and the wiring lines 101b are alternately arranged on the front side 100a of the body 100. The reason is that, on the back between the pads on one side of the overlap portion 105, the pads on the other side are arranged for such an arrangement, as discussed later.

In the overlap portion 105, the width of wiring line 101b is formed so as to be narrower than other part. The reason is to provide a distance as large as possible between the wiring line 101b and the front-side pad 103 in the overlap portion 105 and thus to relieve cross talk.

The wiring lines 101 can be classified into signal wiring lines S and ground wiring lines G. In this case, a wiring pattern composed of repeatedly-arranged wiring pattern units each of which is composed of three wiring lines is formed on the front side 100a of the body 100. Each of the wiring pattern units is formed of the ground wiring line G and two signal wiring lines that are arranged so as to interpose the ground line between them. Accordingly, on the back between the signal pads on one side of the overlap portion 105, the ground pads on the other side are arranged, thus, it is possible to relieve signal pad reflection and cross talk. In addition, since the impedance of the line and the pad is ensured, desired impedance can be designed based on adjustment of material, line width, and line thickness.

The two signal wiring lines included in the wiring pattern unit are a signal wiring line +S and a signal wiring line −S that have signal phases inverted from each other. Since the ground wiring line G is located between differential wiring lines +S and −S of positive phase and inverted phase, it is possible to effectively relieve cross talk of the positive-phase and inverted-phase signals of the differential signals. Accordingly, in pseudo differential transmission such as HDMI and DVI, signal waveform degradation is reduced. In addition, in the case where, in each of the wiring pattern units, the signal wiring line +S and the signal wiring line −S are arranged symmetrically to the ground wiring line G, it is more preferable to relieve differential signal cross talk and to control impedance.

Between the wiring pattern units adjacent to each other, the signal wiring lines +S and −S are located adjacent to each other. It is preferable that the distance between the signal wiring lines +S and −S adjacent to each other is as large as possible. Since the area of the body 100 is limited, actually, the distance between the signal wiring lines +S and −S adjacent to each other is preferably provided so as to be larger than the distance between each of the signal wiring lines +S and −S, and the ground wiring line G adjacent to each other. In other words, the distance between the wiring pattern units is longer than the distance between each of the signal wiring lines +S and —S, and the ground wiring line G in each of the wiring pattern units. It is possible to relieve reflection and cross talk in the positive-phase and inverted-phase wiring lines of the differential signals adjacent to each other.

### (3) Front-Side Pad and Back-Side Pad

The front-side pads 103 and back-side pads 104 for connector connection are formed in the body 100. The front-side pads 103 and the back-side pads 104 are connected to respective ends of wiring lines 101, and are formed so as to be wider than the wiring lines 101. In addition, the front-side pads 103 are formed on the overlap portion front side 105a. The front-side pads 103 are connected to the wiring lines 101a on the front side 100a of the body 100. On the other hand, the back-side pads 104 are formed on the overlap portion back side 105b. The back-side pads 104 are connected to the wiring lines 101b that turn from the front side to the back side of the overlap portion 105 on the overlap portion back surface side 105b.

As shown in FIG. 3(c), on the back between the pads on one side of the overlap portion 105, the pads on the other side are arranged. Accordingly, the distance between the front-side pads, the distance between the back-side pads, and the distance of the front-side pad and the back-side pad are easily and sufficiently provided to relieve cross talk between the pads. Additionally, in the case where the pad intervals on the both front and back sides are set the same as each other, it is suitable to mount a connector.

In addition, the front-side pads 103 and the back-side pads 104 can be classified into the signal pad and the ground pad. As shown in FIG. 3(c), on the back between the signal pads on one side of the overlap portion 105, the ground pads on the other side are arranged. Accordingly, it is possible to relieve cross talk between the signal pads that transmit differential signals.

Additionally, a plurality of overlap portions can be formed to mount three or more connectors similarly to the first embodiment. Furthermore, the connectors to be mounted to this flexible printed board can be separate connectors on the front and back sides, or can be a connector that is partially integrated or is integrated so as to be used for the front and back sides similarly to the first embodiment.

### [Effect]

According to the flexible printed board of the aforementioned construction, since the wiring lines 101 are formed only on one side, the area of the flexible printed board can be small, thus, it is possible to suppress its cost. On the other hand, since the pads 103 and 104 that connect connectors are formed on the front and back sides of the overlap portion 105, in other words, they are formed on the both sides of the board, a plurality of connectors can be connected to the board. The two signal wiring line +S and −S are arranged so as to sandwich the ground wiring line G, thus, it is possible to relieve cross talk between the signal wiring lines +S and −S. In the case where the distance between the signal wiring lines +S and −S is provided so as to be larger than the distance between each of the signal wiring lines +S and −S and the ground wiring line G, it is possible to relieve cross talk between the signal wiring lines S.

Since, in the overlap portion 105, on the back between the signal pads on one side adjacent to each other, the ground pads on the other side are arranged, it is possible to relieve cross talk between the signal pads.

In addition, since the impedance of the line and the pad is ensured, desired impedance can be designed based on adjustment of material, line width, and line thickness.

That is, it is possible to achieve a flexible printed board that is adapted to a plurality of connectors, and is suitable for high-speed transmission at low cost.

### Other Embodiment

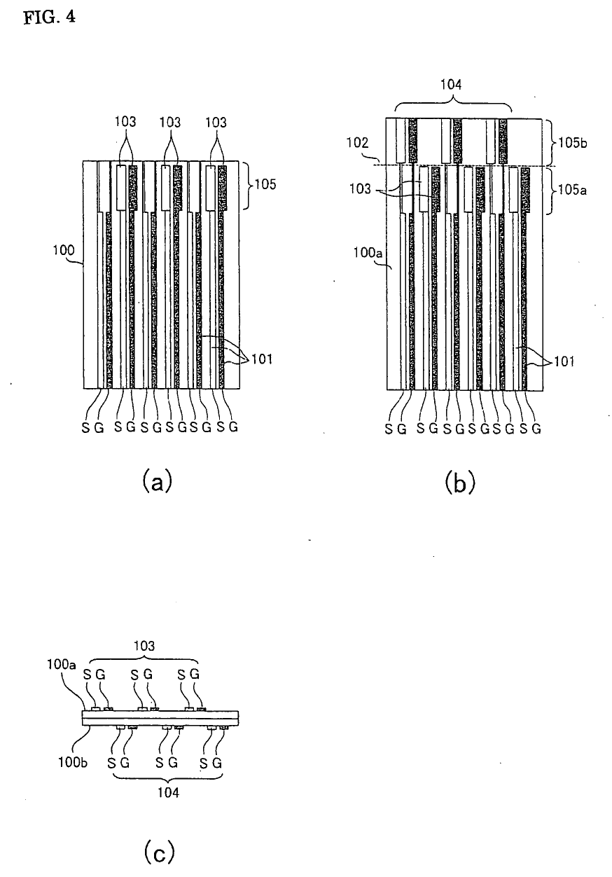

(A) FIG. 4 shows a flexible printed board of another construction example that can mount a plurality of connectors, and relieves cross talk at low cost. FIG. 4(a) is a plan view of the flexible printed circuit board according to this embodiment. The flexible printed board includes a body 100, wiring lines 101, and front-side pads 103. This flexible printed board is doubled in an overlap portion 105. The board includes back-side pads 104 (see FIGS. 4(b) and (c)) on the side of the overlap portion 105 opposite to the paper plane in the figure. FIG. 4(b) is a plan view of the flexible printed circuit board with the overlap portion 105 being developed. The overlap portion 105 is developed to a front side 105a and a back side 105b. FIG. 4(c) is a cross-sectional view of the overlap portion 105 in the same Fig. (a).

As for the wiring lines 101, wiring lines 101a connected to the front-side pads 103, and wiring lines 101b connected to back-side pads 104 are alternatively arranged every two lines. The wiring lines 101 can be classified into signal wiring lines S and ground wiring lines G. The signal wiring lines S and the ground wiring lines G are alternatively arranged. The signal wiring line S and the ground wiring line G compose a pair. A wiring pattern is formed by repeating the pairs. The signal wiring line S and the ground wiring line G that compose the pair are connected to the front-side pad 103 together, or are connected to the back-side pads 104 together. The interval between the signal wiring line S and the ground wiring line G that compose the pair is set shorter than the interval between different pairs.

Thus, as shown in FIGS. 4(b) and (c), in either the front side 105a or the back surface side 105b of the overlap portion, the signal pad and the ground pad are alternately arranged. In addition, on the back between pairs of the signal pads and the ground pads on one side, the signal pad and the ground pad on the other side are arranged. Accordingly, it is possible to suppress effect of cross talk between the signal pads. In addition, since the impedance of the line and the pad is ensured, desired impedance can be designed based on adjustment of material, line width, and line thickness.

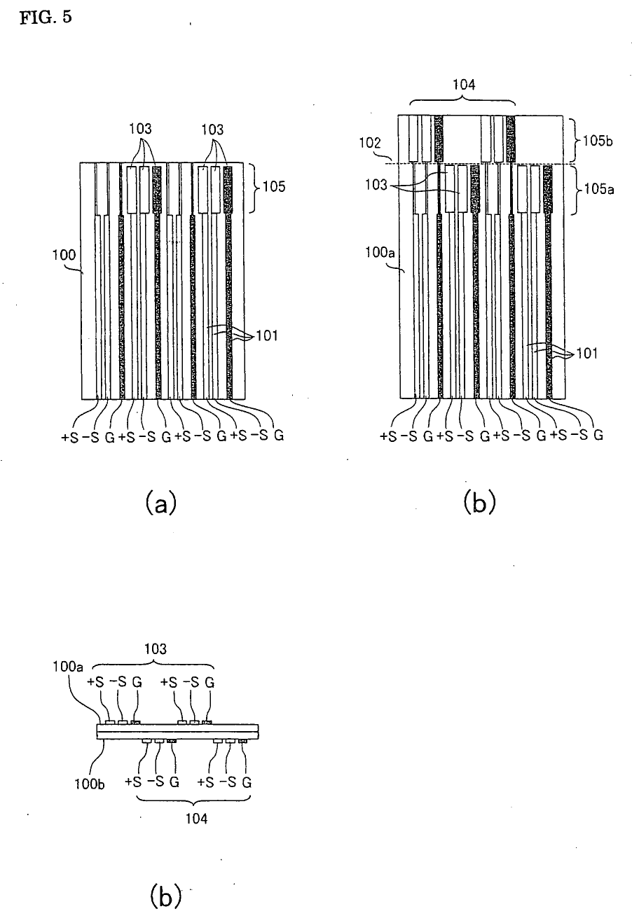

(B) FIG. 5 shows a flexible printed board of another construction example that can mount a plurality of connectors, and relieves cross talk at low cost. FIG. 5(a) is a plan view of the flexible printed circuit board according to this embodiment. The flexible printed board includes a body 100, wiring lines 101, and front-side pads 103. This flexible printed board is doubled in an overlap portion 105. The board includes back-side pads 104 (see FIGS. 5(b) and (c)) on the side of the overlap portion 105 opposite to the paper plane in the figure. FIG. 5(b) is a plan view of the flexible printed circuit board with the overlap portion 105 being developed. The overlap portion 105 is developed to a front side 105a and a back side 105b. FIG. 4(c) is a cross-sectional view of the overlap portion 105 in the same Fig. (a).

As for the wiring lines 101, wiring lines 101a connected to the front-side pads 103, and wiring line 101b connected to back-side pads 104 are alternatively arranged every three lines. These three wiring lines 101 compose a wiring pattern unit.

The wiring lines 101 can be classified into signal wiring lines S and ground wiring lines G. As for one wiring pattern unit, signal wiring lines +S and −S that have signal phases inverted from each other, and the ground line G are formed in order of +S, −S and G. The signal wiring line S and the ground wiring line G compose a pair. A wiring pattern is formed by repeating the pairs. In order to increase coupling between the differential signal wiring lines +S and −S, the differential signal wiring lines +S and −S are preferably located close to each other. Its should be appreciated that the positive phase and the inverted phase of the differential signals can have either arrangement, and they may be arranged in order of −S, +S and G. In addition, since the impedance of the line and the pad is ensured, desired impedance can be designed based on adjustment of material, line width, and line thickness.

Thus, as shown in FIGS. 4(b) and (c), in either the front side 105a or the back surface side 105b of the overlap portion, the differential signal pads and the ground pad are alternately arranged. In addition, on the back between groups of the differential signal pads and the ground pads on one side, group of the differential signal pads and the ground pad on the other side is arranged. Accordingly, it is possible to eliminate effect of cross talk between the differential signals, thus, in differential transmission such as USB and IEEE 1394, signal waveform degradation is reduced.

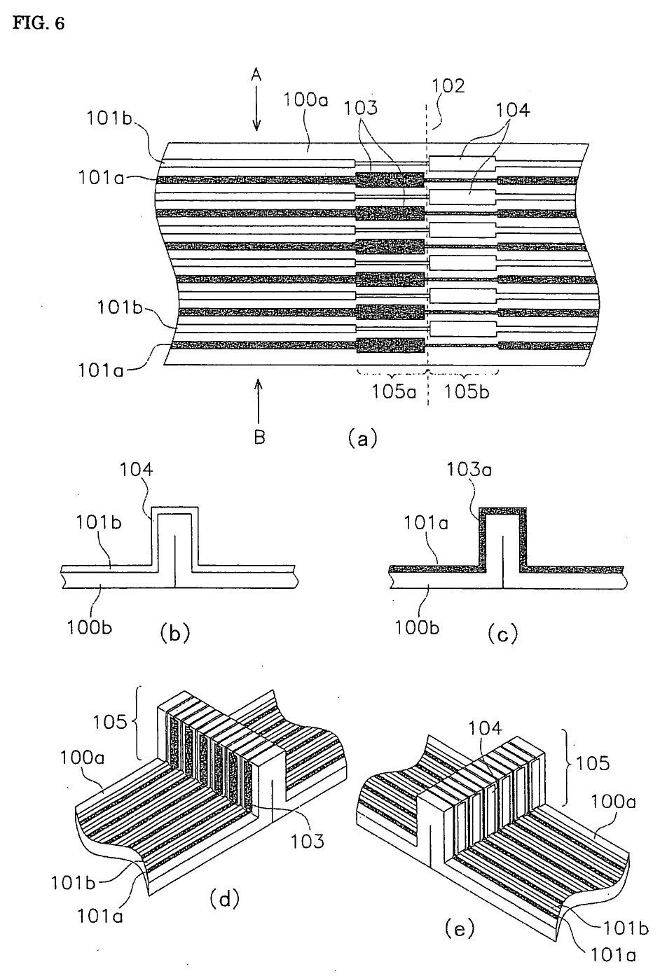

(C) FIG. 6 shows a flexible printed board of another construction example with pads formed at midway points of the wiring lines 101. FIG. 6(a) is a plan view of a developed flexible printed circuit board according to this embodiment. FIG. 6(b) is a side view of the flexible printed board when viewed from a side A in the same Fig. (a). FIG. 6(c) is a side view of the flexible printed board when viewed from a side B in the same Fig. (a). FIG. 6(d) is a perspective view of the flexible printed board when viewed from one direction. FIG. 6(e) is a perspective view of the flexible printed board when viewed from another direction.

In this flexible printed board, an overlap portion 105 is formed in the midway points of the wiring lines 101. A front-side pad 103 is interposed at the midway point of wiring lines 101a, and is connected to the wiring line 101a in serial. The front-side pad 103 is formed on the surface of the overlap portion 105 on one side, i.e., on a front side 100a of the body 100. A back-side pad 104 is interposed at the midway point of a wiring line 101b, and is connected to the wiring line 101b in serial. The back-side pad 104 is formed on the surface of the overlap portion 105 on the one side, i.e., on a front side 100a of the body 100. In addition, the front-side pad 103 and the back-side pad 104 are formed in the overlap portion 105 on the sides opposite to each other.

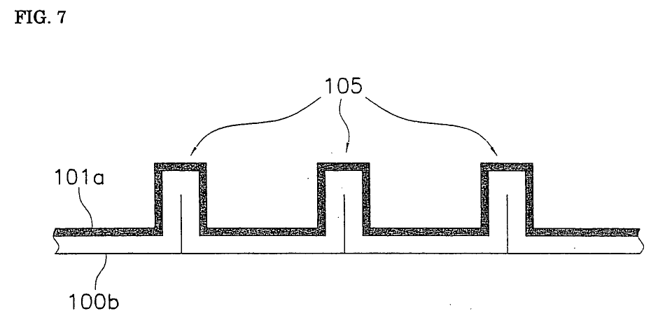

FIG. 7 shows construction where pads 103 and 104, and overlap portions 105 are formed at a plurality of midway points of a long board body 100. In the case where the construction of FIG. 6 is applied to form a plurality of overlap portions, a plurality of connectors can be connected to the flexible printed board, thus, it is possible to increase a degree of freedom in connection form.

### INDUSTRIAL APPLICABILITY

A flexible printed board according to the present invention can be applied, in a high-speed interface that has a problem of signal reflection and cross talk, as an interface transmission medium with a plurality of ports.

1. A flexible printed board comprising:
a flexible printed board body that has mutually opposing first and second sides, and an overlap portion that overlaps the second side such that the first side becomes the outer surface thereof by bending at least a part of said first side;
a plurality of wiring lines that are arranged on the first side of said body substantially in parallel to each other;
first pads that are connected to ends and/or midway points of a portion of the wiring lines, the first pads wider than the wiring lines connected thereto, and formed on one side of said overlap portion; and
second pads that are connected to ends and/or midway points of a portion of the wiring lines, the second pads wider than the wiring lines connected thereto, and formed on the other side of said overlap portion, wherein
the wiring lines with said first pads connected thereto and the wiring lines with said second pads connected thereto are alternately arranged on said first side.

2. A flexible printed board set forth in claim 1, wherein said wiring lines include signal wiring lines and ground wiring lines, and said signal wiring lines and said ground wiring lines are arranged so as to alternate every two lines.

3. A flexible printed board set forth in claim 2, wherein the distance between the signal wiring lines adjacent to each other is longer than the distance between the ground wiring lines adjacent to each other.

4. A flexible printed board set forth in claim 1, wherein a wiring pattern composed of repeating wiring pattern units each composed of three wiring lines is formed on said first side, and each of said wiring pattern units is formed of a ground wiring line and two signal wiring lines that are arranged so as to interpose the ground line therebetween.

5. A flexible printed board set forth in claim 4, wherein the two signal wiring lines included in said wiring pattern unit are a first signal wiring line and a second signal wiring line that have signal phases inverted from each other, and in each of said wiring pattern units, said first signal wiring line and said second signal wiring line are arranged symmetrically with respect to said ground wiring line.

6. A flexible printed board set forth in claim 4, wherein the distance between said wiring pattern units that compose said wiring pattern is longer than the distance between the signal wiring line and the ground wiring line in each of said wiring pattern units.
